(19) United States
(12) Patent Application Publication
(10) Pub. No.: US 2006/0017671 A1
(43) Pub. Date: Jan. 26, 2006

(54) Display device and electronic apparatus

(75) Inventor: Tadashi Yamada, Matsumoto-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/167,267

(22) Filed: Jun. 28, 2005

(30) Foreign Application Priority Data
Jul. 23, 2004 (JP) 2004-215326
Jul. 23, 2004 (JP) 2004-215328

(51) Int. Cl. G09G 3/30

(52) U.S. Cl. 345/77

(57) ABSTRACT

A display device includes a display region, and the display region has a first display region that is composed of a first pixel group displaying a first light-emitting wavelength range; and a second display region that is composed of a second pixel group displaying a second light-emitting wavelength range different from the first light-emitting wavelength range.

### CROSS-REFERENCE TO RELATED APPLICATIONS

This application claims priorities to Japanese Patent Application Nos. 2004-215326 and 2004-215328, filed on Jul. 23, 2004, the entire disclosures of which are incorporated herein by reference.

### BACKGROUND

The present invention relates to a display device and to an electronic apparatus.

Since a self-emitting display device, such as an organic EL device, does not need to have a backlight, it has drawn attention as a display device having a small size. In the organic EL device, sub-pixels (minimum display units) corresponding to red (R), green (G), and blue (B) are arranged in stripes, and three sub-pixels constitute one pixel to perform full-color display (for example, see Japanese Unexamined Patent Application Publication No. 2002-252083).

In the display device disclosed in Japanese Unexamined Patent Application Publication No. 2002-252083, full-color display is performed by a structure common to pixels in a display region. This structure is suitable for a case in which display is performed such that a time integral value of the brightness in the display region is constant in every pixel, as in a television. However, when the time integral value of brightness in the display region is different for every pixel, the following problems arise. That is, 1) in a color pixel having a large time integral value of brightness, the brightness is more easily deteriorated than the other color pixels; 2) in the color pixel having a large time integral value of brightness, the deterioration of brightness occurs relatively rapidly, and the whole white balance collapses. Thus, the color is changed, and image quality is easily deteriorated, and 3) when sub-pixels corresponding to three colors are arranged in a monochrome display region, an aperture ratio is lowered, and thus the brightness of the monochrome display portion is rapidly deteriorated.

### SUMMARY

An advantage of the invention is that it provides a display device capable of improving display quality and of increasing life-span. Further, another advantage of the invention is that it provides an electronic apparatus having a high-quality display device.

According to a first aspect of the invention, a display device includes a display region having a first display region that is composed of a first pixel group displaying a first light-emitting wavelength range; and a second display region that is composed of a second pixel group displaying a second light-emitting wavelength range different from the first light-emitting wavelength range. Here, the first light-emitting wavelength range is not equal to the second light-emitting wavelength range. That is, the first light-emitting wavelength range may not be completely equal to the second light-emitting wavelength range, and one light-emitting wavelength range may be included in the other light-emitting wavelength range.

In the display device, the first pixel group of the first display region and the second pixel group of the second display region have different light-emitting wavelength ranges. That is, in the first and second display regions, the ranges (kinds) of color light components to be emitted are different from each other.

Therefore, the display region which the display device of the invention has is divided into at least the first and second display regions emitting different color light components, so that the flexibility of the design of the display region can be improved.

In this case, pixels to emit a light component corresponding to a color necessary for a predetermined region in the display regions are arranged, and pixels to emit a light component corresponding to a color unnecessary for the predetermined region are excluded. As a result, it is possible to increase an aperture ratio. That is, according to the related art, since pixels for full-color display are arranged in the display region for performing monochrome display, pixels to emit the light components corresponding to the unnecessary colors are arranged, which causes the aperture ratio to be lowered. In the invention, since the pixels related to the unnecessary colors are excluded, the problem of the aperture ratio being lowered can be solved.

In addition, only the pixels related to the necessary colors constitute a predetermined display region. Therefore, even if brightness per one pixel is deteriorated, compared to a case in which the pixels for full-color display are arranged in the entire display region as in the related art, it is possible to obtain the same surface brightness as that in the related art. Therefore, the deterioration of brightness per one pixel can be prevented, and consumption power can be reduced. In addition, it is possible to prolong the life span of brightness.

In addition, in the display device, resolution can increase. That is, as compared to a case in which the pixels for full-color display are arranged in the entire display region, it is possible to increase the number of pixels corresponding to necessary colors in the predetermined region and thus to increase resolution.

Preferably, the first pixel group is composed of pixels that can display plural kinds of color light components, and the second pixel group is composed of pixels that can display a color light component. In this case, in the first display region, two-color display or plural color display can be performed, but in the second display region, only monochrome display can be performed. In addition, as compared to a case in which the pixels for the full-color display are arranged, as in the related art, the aperture ratio, the resolution, and the life span of brightness can increase in the second display region. More particularly, it is preferable that the first pixel group be composed of pixels each including at least a first sub-pixel to emit a predetermined color light component and a second sub-pixel to emit another color light component different from the light component emitted by the first sub-pixel, and that the second pixel group be composed of pixels each having one sub-pixel to emit a predetermined color light component.

Further, it is preferable that the first pixel group be composed of pixels to perform full-color display and that the second pixel group be composed of pixels to perform monochrome display. More particularly, the first pixel group can be composed of pixels each having a sub-pixel to emit a red light component, a sub-pixel to emit a green light component, and a sub-pixel to emit a blue light component. The second pixel group can be composed of pixels each having two or fewer sub-pixels selected from among the sub-pixel to emit the red light component, a sub-pixel to emit a green light component, and a sub-pixel to emit a blue light component.

It is preferable that, when the plural kinds of sub-pixels are provided, various sub-pixels have the same size. In this case, the aperture ratio can be adjusted by the number of sub-pixels formed on the display region, and the design of the aperture ratio can be facilitated. Further, it is preferable that the sub-pixels each have a rectangular shape, and that the pixel includes a plurality of the sub-pixels having the rectangular shape and have a square shape.

According to a second aspect of the invention, an electronic apparatus includes the above-mentioned display device. By using this electronic apparatus, it is possible to achieve high-definition display on the display unit.

According to a third aspect of the invention, there is provided a display device including a display region composed of a plurality of pixels. The pixel is composed of a laminated structure of a plurality of functional layers. The display region has a first display region that is composed of a first pixel group displaying a first light-emitting wavelength range and a second display region that is composed of a second pixel group displaying a second light-emitting wavelength range different from the first light-emitting wavelength range. The first pixel constituting the first pixel group and the second pixel constituting the second pixel group have different laminated structures of the functional layers. Here, the first light-emitting wavelength range is not equal to the second light-emitting wavelength range. That is, the first light-emitting wavelength range may not be completely equal to the second light-emitting wavelength range, and one light-emitting wavelength range may be included in the other light-emitting wavelength range.

In the display device, the first pixel group of the first display region and the second pixel group of the second display region have different light-emitting wavelength ranges. That is, in the first and second display regions, the ranges (kinds) of color light components to be emitted are different from each other.

Therefore, the display region which the display device of the invention has is divided into at least the first and second display regions each emitting different color light components, so that the flexibility of the design of the display region can be improved.

In this case, pixels to emit a light component corresponding to a color necessary for a predetermined region in the display regions are arranged, and pixels to emit a light component corresponding to a color unnecessary for the predetermined region are excluded. As a result, it is possible to raise an aperture ratio. That is, according to the related art, since pixels for full-color display are arranged in the display region for performing monochrome display, pixels to emit the light components corresponding to the unnecessary colors are arranged, which causes the aperture ratio to be lowered. In the invention, since the pixels related to the unnecessary colors are excluded, the problem of the aperture ratio being lowered can be solved.

In addition, only the pixels related to the necessary colors constitute a predetermined display region. Therefore, even if brightness per pixel is reduced, compared to a case in which the pixels for full-color display are arranged in the entire display region as in the related art, it is possible to obtain the same surface brightness as that in the related art. Therefore, the deterioration of brightness per pixel and consumption power can be reduced, and the life span of brightness can be prolonged.

In addition, in the display device, resolution can increase. That is, as compared to a case in which the pixels for full-color display are arranged over the entire display region, it is possible to increase the number of pixels corresponding to necessary colors in a predetermined region and thus to increase resolution.

In the structure in which the display region is divided for each color light component to be emitted, the laminated structure of the functional layers constituting the pixel is different for every divided display region. When emission colors are different, the energy required for performing the light emission is different, so that each pixel corresponding to each color has the desirable structure. However, when the pixels for full-color display are arranged over the entire display region, as in the related art, it is necessary that the pixel structure be changed according to the pattern of each color. As a result, a workload becomes large. However, in the invention, since the display region is divided, the laminated structure of the functional layers may be different for each display region, and the laminated structure suitable for each color can be achieved.

In this way, by making the functional layer different for each region, the laminated structure suitable for the luminescent color of the pixel can be employed, and thus light-emitting efficiency and the life span of brightness can be improved.

Preferably, the first pixel group is composed of pixels that can display plural kinds of color light components, and the second pixel group is composed of pixels that can display a color light component. In this case, the two-color display can be performed in the first display region, but the monochrome display can be performed in the second display region. Further, as compared to the case in which the pixels for full-color display are provided, as in the related art, the aperture ratio, the resolution, and the life span of brightness can be improved in the second display region. Particularly, it is preferable that the first pixel group be composed of first pixels each including at least a first sub-pixel to emit a predetermined color light component and a second sub-pixel to emit another color light component different from the color light component emitted by the first sub-pixel, and that the second pixel group be composed of second pixels each having one sub-pixel to emit a predetermined color light.

Further, it is preferable that the first pixel group be composed of pixels to perform full-color display, and that the second pixel group be composed of pixels to perform monochrome display. Particularly, it is preferable that the first pixel group be composed of first pixels each having a sub-pixel to emit a red light component, a sub-pixel to emit a green light component, and a sub-pixel to emit a blue light component, and that the second pixel group be composed of second pixels each having two or fewer sub-pixels selected from among the sub-pixel to emit the red light component, the sub-pixel to emit the green light component, and the sub-pixel to emit the blue light component.

When the plurality of sub-pixels are provided, the sub-pixels may have the same size. In this case, the aperture ratio can be controlled by the number of the sub-pixels formed on the display region, and the aperture ratio can be easily designed. It is preferable that the sub-pixel have a rectangular shape, and that the pixel have a plurality of the sub-pixels having the rectangular shape and have a square shape.

A functional layer included in the display device may have a cathode layer, an anode layer, and an organic EL layer formed between the cathode layer and the cathode layer. In this case, it is preferable that the first pixel group be composed of first pixels each having a sub-pixel to emit a blue light component, that the second pixel group be composed of second pixels each having a sub-pixel to emit a red light component and not having the sub-pixel to emit the blue light component, that a cathode layer constituting the functional layer of the first pixel contain lithium fluoride, and that a cathode layer constituting a functional layer of the second pixel do not contain lithium fluoride.

The organic EL layer, serving as a light-emitting functional layer, has different light-emitting efficiency for each light-emitting color. Particularly, in the organic EL layer to emit a red light component and the organic EL layer to emit a blue light component, since the light-emitting efficiencies are greatly different because of the difference in the structure of the cathode layer, it is preferable for the organic EL layers to have a suitable cathode layer structure. More particularly, by containing lithium fluoride in the cathode layer, the light-emitting efficiency of the blue organic EL layer can be improved. However, the light-emitting efficiency of the red organic EL layer is a little lowered. Therefore, when the display region is divided, as in the invention, it is possible to easily make the structures of the cathode layer different from each other for the divided display region. More particularly, in the display region composed of the first pixels including the blue sub-pixels and the display region composed of the second pixels including the red sub-pixels and not including the blue sub-pixels, it is possible to easily make the structures of the cathode layer of each pixel different from each other, and the light-emitting efficiency can be easily improved.

As such, when the organic EL layer is included as a functional layer, the first pixel group is composed of first pixels each having a sub-pixel to emit a red light component, a sub-pixel to emit a green light component, and a sub-pixel to emit a blue light component, and the second pixel group is composed of second pixels each having the sub-pixel to emit the red light component. In addition, a cathode layer constituting a functional layer of the first pixel contains lithium fluoride, and a cathode layer constituting a functional layer of the second pixel does not contain lithium fluoride. In this case, it is possible to easily make the structures of the cathode layer of each pixel different from each other, and light-emitting efficiency can be easily improved.

As the structure of the cathode layer, it is preferable that the cathode layer constituting the functional layer of the first pixel have a complex structure of lithium fluoride, calcium, and aluminum, and that the cathode layer constituting the functional layer of the second pixel have a complex structure of calcium and aluminum.

According to a fourth aspect of the invention, an electronic apparatus includes the above-mentioned display device. By using this electronic apparatus, high-definition display can be performed for a long time in the display unit.

### BRIEF DESCRIPTION OF THE DRAWINGS

The invention will be described with reference to the accompanying drawings, wherein like numbers reference like elements, and wherein:

FIG. 1 is a circuit diagram of an organic EL device according to a first embodiment of the invention;

FIG. 2 is a diagram showing the plan-view structure of the organic EL device shown in FIG. 1;

FIG. 3 is a diagram showing the plan-view structure of a pixel in a first display region;

FIG. 4 is a diagram showing the plan-view structure of a pixel in a second display region;

FIG. 5 is a diagram showing the sectional structure of the first display region;

FIG. 6 is a diagram showing the sectional structure of the second display region;

FIG. 7 is a graph showing a temporal change of brightness in the first embodiment and a temporal change of brightness in a comparative example;

FIG. 8 is a diagram illustrating a method of manufacturing the organic EL display device according to the first embodiment;

FIG. 9 is a diagram illustrating the method of manufacturing the organic EL display device according to the first embodiment;

FIG. 10 is a diagram illustrating the method of manufacturing the organic EL display device according to the first embodiment;

FIG. 11 is a diagram illustrating the method of manufacturing the organic EL display device according to the first embodiment;

FIG. 12 is a diagram illustrating the method of manufacturing the organic EL display device according to the first embodiment;

FIG. 13 is a diagram illustrating the first display region in the method of manufacturing the organic EL display device according to the first embodiment;

FIG. 14 is a diagram illustrating the second display region in the method of manufacturing the organic EL display device according to the second embodiment;

FIG. 15 is a diagram illustrating the first display region in the method of manufacturing the organic EL display device according to the first embodiment;

FIG. 16 is a diagram illustrating the second display region in the method of manufacturing the organic EL display device according to the second embodiment;

FIG. 17 is a diagram showing the plan-view structure of a head according to the first embodiment of the invention;

FIG. 18 is a diagram showing the plan-view structure of an inkjet device according to the first embodiment of the invention;

FIG. 19 is a plan view showing an example of a substrate constituting a display unit mounted on an electronic apparatus;

FIG. 20 is a cross-sectional view showing the structure of a substrate constituting the display unit shown in FIG. 19;

FIG. 21 is a plan view showing the structure of a display region in the display unit shown in FIG. 19;

FIG. 22 is a plan view showing an example of an electronic apparatus;

FIG. 23 is a plan view showing a modification of the substrate constituting the display unit mounted on the electronic apparatus;

FIG. 24 is a plan view showing an example of an electronic apparatus;

FIG. 25 is a diagram showing the sectional structure of a first display region in an organic EL display device according to a second embodiment of the invention;

FIG. 26 is a diagram showing the sectional structure of a second display region in the organic EL display device according to the second embodiment of the invention;

FIG. 27 is a graph showing a temporal change of brightness in the second embodiment and a temporal change of brightness in a comparative example;

FIG. 28 is a graph showing the difference between a temporal change of brightness when a lithium fluoride layer is provided and a temporal change of brightness when the lithium fluoride layer is not provided;

FIG. 29 is a diagram illustrating the first display region in a method of manufacturing the organic EL display device according to the second embodiment; and

FIG. 30 is a diagram illustrating the second display region in the method of manufacturing the organic EL display device according to the second embodiment.

### DETAILED DESCRIPTION OF EMBODIMENTS

Hereinafter, an organic EL device, which is a display device according to first and second embodiments of the invention, and a method of manufacturing the same will be described in detail with reference to the accompanying drawings. In addition, in the respective drawings, in order for each layer or member to be recognizable, each layer or member is shown with a different scale.

Organic EL Device

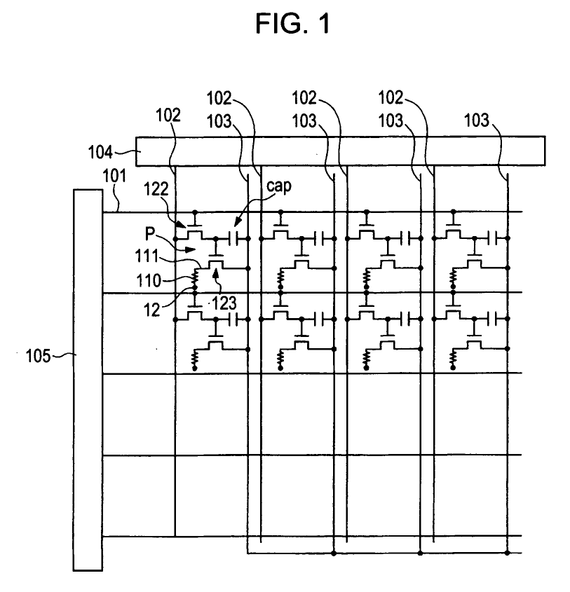

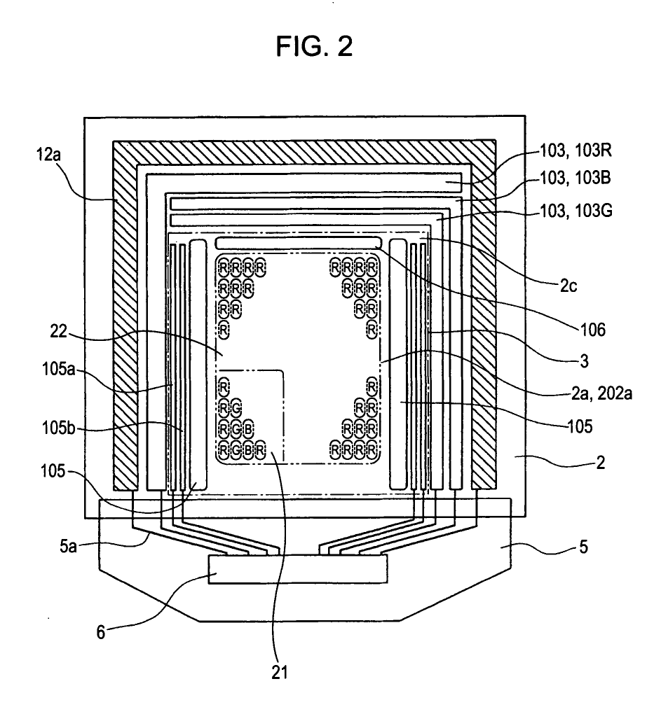

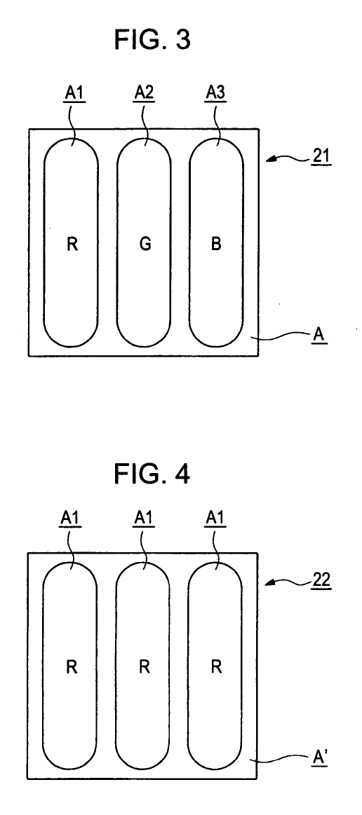

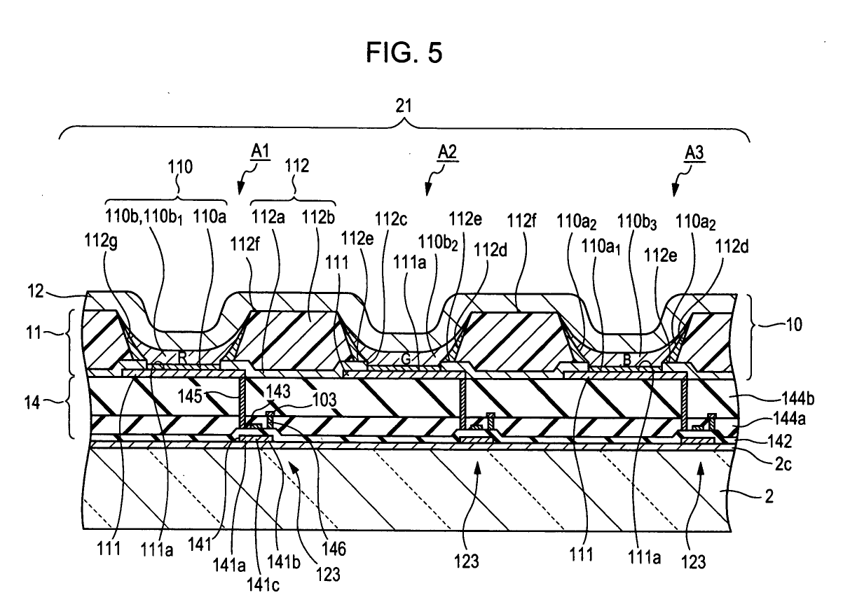

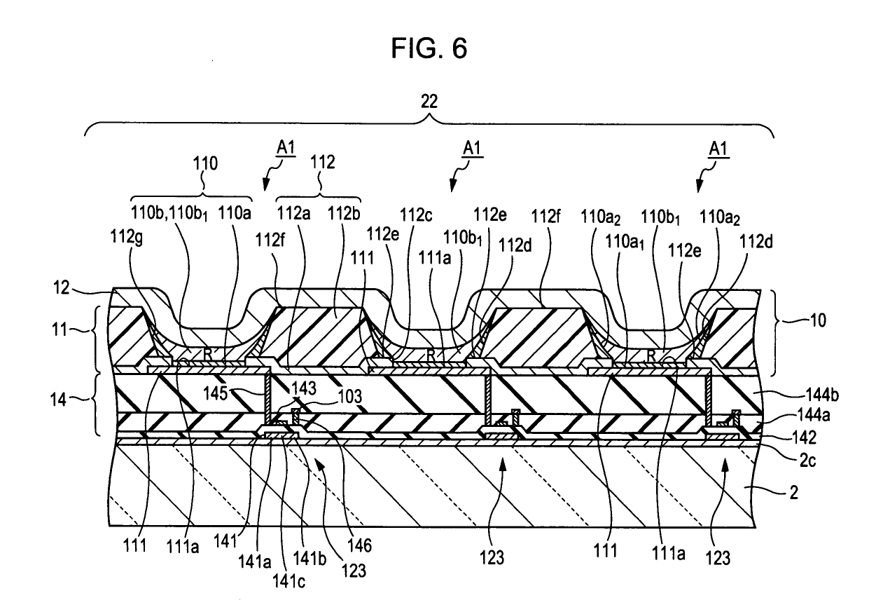

FIG. 1 is an explanatory diagram showing the wiring structure of an organic EL device according to a first embodiment of the invention, and FIG. 2 is a plan view schematically illustrating the organic EL device according to the first embodiment. FIGS. 3 and 4 are enlarged plan views schematically showing the structure of a pixel, and FIGS. 5 and 6 are cross-sectional views schematically illustrating a display region of the organic EL device according to the first embodiment.

As shown in FIG. 1, the organic EL device according to the present embodiment includes a plurality of scanning lines 101, a plurality of signal lines 102 extending perpendicular to the plurality of scanning lines 101, and a plurality of power lines 103 extending parallel to the plurality of signal lines 102. Here, unit display regions P are respectively provided so as to correspond to intersections of the scanning lines 101 and the signal lines 102.

The signal lines 102 are connected to a data line driving circuit 104 which includes a shift register, a level shifter, video lines and analog switches. In addition, the scanning lines 101 are connected to a scanning line driving circuit 105 which includes a shift register and a level shifter.

In addition, each unit display region P is provided with a switching thin film transistor 122 having a gate electrode supplied with a scanning signal through the scanning line 101, a storage capacitor cap for holding a pixel signal supplied from the signal line 102 through the switching thin film transistor 122, a driving thin film transistor 123 having a gate electrode supplied with the pixel signal held in the storage capacitor cap, a pixel electrode (electrode) 111 to which a driving current flows from the power line 103 when it is electrically connected to the power line 103 through the driving thin film transistor 123, and an organic EL layer 110 interposed between the pixel electrode 111 and a cathode layer (counter electrode) 12. The electrode 111, the counter electrode 12, and the organic EL layer 110 constitute a light-emitting element.

When the scanning line 101 is driven and the switching thin film transistor 122 is turned on, the potential of the signal line 102 is held in the storage capacitor cap, and the on/off state of the driving thin film transistor 123 is determined in accordance with the state of the storage capacitor cap. In addition, a current flows to the pixel electrode 111 from the power line 103 through a channel of the driving thin film transistor 123, and then the current flows to the cathode layer 12 through the organic EL layer 110. In the organic EL layer 110, light is emitted in accordance with the amount of current flowing.

As shown in FIGS. 5 and 6, the organic EL device according to the present embodiment includes a transparent substrate 2 made of, for example, glass, a light-emitting element portion 11 formed on the substrate 2 and having light-emitting elements arranged in a matrix, and the cathode layer 12 formed on the light-emitting element portion 11. Here, the light-emitting element portion 11 and the cathode layer 12 constitute a display element 10. The substrate 2 is a transparent substrate made of, for example, glass. As shown in FIG. 2, the substrate 2 is divided into two regions, that is, a display region 2a located at a central portion of the substrate 2 and a non-display region 2c located at the periphery of the substrate 2 for surrounding the display region 2a.

The display region 2a is a region formed of light-emitting elements arranged in a matrix and has a plurality of dots (sub-pixels) each of which can emit a light component corresponding to any one of red (R), green (G), and blue (B). Here, each dot (sub-pixel) serves as a minimum display unit for display and constitutes the unit display region P shown in FIG. 1. In addition, according to the present embodiment, the display region 2a has a first display region 21 to perform full-color display and a second display region 22 to perform monochrome display. As shown in FIG. 3, the first display region 21 has a plurality of pixels each composed of an R dot A1 to emit a red (R) light component, a G dot A2 to emit a green (G) light component, and a B dot A3 to emit a blue (B) light component arranged therein. On the other hand, as shown in FIG. 4, the second display region 22 has a plurality of pixels A′ each including three R dots A1 to emit the red (R) light component arranged therein.

That is, in the display region 2a, the plurality of pixels A and A′ are disposed in a predetermined arrangement. The pixels A and A′ have different wavelength ranges to emit light. That is, the pixel A can emit light having the wavelength range of full color (approximately, a wavelength of 380 to 780 mn), and the pixel A′ can emit light having the wavelength range of red (approximately, a wavelength of 580 to 780 nm). In addition, a display region in which the plurality of pixels A constitute a first pixel group having a predetermined pattern functions as the first display region 21 capable of performing full-color display. In addition, a display region in which the plurality of pixels A′ constitute a second pixel group having a predetermined pattern functions as the second display region 22 capable of performing red display. As shown in FIGS. 3 and 4, the respective dots (sub-pixels) A1, A2, and A3 have the same rectangular shape and the same area, and the respective pixels A and A′ have substantially the same square shape.

Referring to FIG. 2 again, the power lines 103 (103R, 103G, and 103B) are provided in the non-display region 2c. The scanning line driving circuits 105 are provided at both sides of the display region 2a. In addition, control signal wiring lines 105a for a driving circuit and power lines 105b for a driving circuit 105b connected to the scanning line driving circuits 105 are provided at both sides of the scanning line driving circuits 105. A test circuit 106 is provided at an upper side of the display region 2a in the drawing to test the quality and defects of a display device during manufacture and shipment.

FIG. 5 is a diagram showing the sectional structure of the first display region 21. The first display region 21 is composed of three types of dots (sub-pixels) A1, A2, and A3, as described above.

In the first display region 21, a circuit element unit 14 on which circuits, such as TFTs, are formed, the light-emitting element portion 11 on which the organic EL layer 110 is formed, and the cathode layer 12 are sequentially laminated on the substrate 2. Light emitted from the organic EL layer 110 toward the substrate 2 passes through the circuit element unit 14 and the substrate 2, and then travels toward a lower side (observer side) of the substrate 2. In addition, the light emitted from the organic EL layer 110 to the opposing side of the substrate 2 is reflected from the cathode layer 12, and then travels toward the lower side (observer side) of the substrate 2 through the circuit element unit 14 and the substrate 2.

In addition, when the cathode layer 12 is made of a transparent material, it is possible to reflect the light emitted from the cathode layer. The transparent materials forming the cathode layer may include ITO (indium tin oxide), Pt, Ir, Ni, and Pt.

In the circuit element unit 14, a base protecting film 2c composed of a silicon oxide film is formed on the substrate 2, and an island-shaped semiconductor film 141 made of polycrystalline silicon is formed on the base protecting film 2c. In the semiconductor film 141, the source region 141a and the drain region 141b are formed by a highly concentrated phosphorous ion implanting method. A portion where the phosphorous ions are implanted becomes a channel region 141c.

Then, a gate insulating film 142 is formed so as to cover the base protecting film 2c and the semiconductor film 141. A gate electrode 143 (the scanning line 101) made of Al, Mo, Ta, Ti, or W is formed on the gate insulting film 142, and a first interlayer insulating film 144a and a second interlayer insulating film 144b which are made of a transparent material are formed on the gate electrode 143 and the gate insulating film 142. The gate electrode 143 is provided at a position adjacent to the channel region 141c of the semiconductor film 141. In addition, contact holes 145 and 146 are formed such that they pass through the first and second interlayer insulating films 144a and 144b to reach source and drain regions 141a and 141b of the semiconductor film 141, respectively.

Further, on the second interlayer insulating film 144b, transparent pixel electrodes 111 made of, for example, ITO are patterned in a predetermined shape, and the contact hole 145 is connected to the pixel electrode 111. In addition, the contact hole 146 is connected to the power line 103. In this way, the driving thin film transistor 123 connected to the pixel electrode 111 is formed in the circuit element unit 14.

The light-emitting element portion 11 is mainly composed of the organic EL layers 110 laminated on the plurality of pixel electrodes 111 and bank portions 112 which are provided between the pixel electrodes 111 and the organic EL layers 110 to partition the respective organic EL layers 110. The cathode layer 12 is arranged on the organic EL layer 110. The pixel electrode 111, the organic EL layer 110, and the cathode layer 12 constitute a light-emitting element. Here, the pixel electrode 111 is made of, for example, ITO and is patterned substantially in a rectangular shape in plan view. The bank portions 112 are provided to partition the pixel electrodes 111.

As shown in FIG. 5, the bank portion 112 has a laminated structure of an inorganic bank layer (first bank layer) 112a, serving as a first partition wall located at the side of the substrate 2, and an organic bank layer (second bank layer) 112b, serving as a second partition wall located away from the substrate 2. The inorganic bank layer 112a is formed of, for example, TiO₂ or SiO₂, and the organic bank layer 112b is formed of, for example, an acrylic resin or a polyimide resin.

The inorganic and organic bank layers 112a and 112b are formed so as to ride on the peripheral edge of the pixel electrode 111. In plan view, the peripheral edge of the pixel electrode 111 and the inorganic bank layer 112a partially overlap each other. In addition, similar to the inorganic bank layer 112a, the organic bank layer 112b overlaps a part of the pixel electrode 111 in plan view. Further, the inorganic bank layer 112a protrudes more toward the central portion of the pixel electrode 111 than toward the edge of the organic bank layer 112b. In this way, a first laminated portion (protruding portion) 112e of the inorganic bank layer 112a is formed at an inner side of the pixel electrode 111, so that a lower opening 112c is formed at a location adjacent to the pixel electrode 111.

In addition, an upper opening 112d is formed in the organic bank layer 112b. The upper opening 112d is formed at a location adjacent to the pixel electrode 111 and the lower opening 112c. As shown in FIG. 5, the upper opening 112d is larger than the lower opening 112c and is smaller than the pixel electrode 111 in diameter. In addition, a top portion of the upper opening 112d may be aligned with the end of the pixel electrode 111. In this case, as shown in FIG. 5, the cross section of the upper opening 112d of the organic bank layer 112b is inclined. In this way, the lower opening 112c and the upper opening 112d communicate with each other to form an opening 112g in the bank portion 112.

In addition, the bank portion 112 has a region having a lyophilic property and a region having a lyophobic property. The regions having the lyophilic property include the first laminated portion 112e of the inorganic bank layer 112a and an electrode surface 111 a of the pixel electrode 111, and these regions are given the lyophilic property by a plasma surface treatment using oxygen as a raw gas. In addition, the regions having the lyophobic property include a wall surface of the upper opening 112d and a top surface 112f of the organic bank layer 112, and these regions are given fluoridated surfaces (lyophobic property) by a plasma treatment using methane tetrafluoride, tetrafluoromethane, or carbon tetrafluoride as a raw gas.

The organic EL layer 110 includes a hole injection/transportation layer 110a laminated on the pixel electrode 111 and a light-emitting layer 110b formed adjacent to the hole injection/transportation layer 110a.

The hole injection/transportation layer 110a has a function for injecting holes into the light-emitting layer 110b and a function for transporting the holes therein. In this way, the hole injection/transportation layer 110a is provided between the pixel electrode 111 and the light-emitting layer 110b, so that it is possible to improve element characteristics, such as the light-emitting efficiency and life span of the light-emitting layer 110b. In addition, in the light-emitting layer 110b, the holes injected from the hole injection/transportation layer 110a and electrons injected from the cathode layer 12 recombine with each other to emit light.

The hole injection/transportation layer 110a includes a flat portion 110a1 which is located inside the lower opening 112c and which is formed on the pixel electrode surface 111a and a peripheral portion 110a2 which is located inside the upper opening 112d and which is formed on the first laminated portion 112e of the inorganic bank layer. In addition, the hole injection/transportation layer 110a is formed only between the inorganic bank layers 112a (between the lower openings 112c) formed on the pixel electrode 111 (may be formed on only the above-mentioned flat portion).

The light-emitting layer 110b is formed over the flat portion 110a1 and the peripheral portion 110a2 of the hole injection/transportation layer 110a, and the thickness of the light-emitting layer 110b on the flat portion 112a1 is within the range of 50 to 80 nm. The light-emitting layer 110b has a red light-emitting layer 110b1 to emit a red (R) light component, a green light-emitting layer 110b2 to emit a light green (G) component, and a blue light-emitting layer 110b3 to emit a blue (B) light component. The respective light-emitting layers 110b1 to 110b3 are arranged in stripes in plan view.

In addition, the hole injection/transportation layer can be made of, for example, a mixture of a polythiophene derivative, such as polyethylenedioxothiophene (PEDOT), and polystyrene sulfonic acid.

In addition, the light-emitting layer 110b can be made of for example, (poly) paraphenylenevinylene derivative, polyphenylene derivative, polyfluorene derivative, polyvinylcarvazole, polythiophene derivative, perylene dye, coumarin dye, rhodamine dye, and materials obtained by doping rubrene, 9,10-diphenylanthracene, tetraphenylbutadiene, Nile red, coumarin 6, quinacridone or the like in these high polymer materials.

The cathode layer 12 is formed over the entire surface of the light-emitting element portion 11 and causes a current to flow in the organic EL layer 110 formed on the pixel electrode 111. For example, the cathode layer 12 is composed of a laminated layer of a calcium layer and an aluminum layer. In this case, it is preferable that a work function be small in a part of the cathode layer adjacent to the light-emitting layer. More particularly, according to the present embodiment, the cathode layer directly comes into contact with the light-emitting layer 110b to inject electrons into the light-emitting layer 110b.

In addition, LiF may be formed between the light-emitting layer 110b and the cathode layer 12 in order to improve the light-emitting efficiency. In addition, the materials forming the red and green light-emitting layers 110b1 and 110b2 are not limited to lithium fluoride, but may be made of other materials. Therefore, in this case, only the blue (B) light-emitting layer 110b3 may be formed of lithium fluoride, the other red and green light-emitting layers 110b1 and 110b2 may be formed of materials other than lithium fluoride. In addition, only the calcium film may be formed on the red and green light-emitting layers 110b1 and 110b2 without forming a film made of lithium fluoride.

In addition, since aluminum forming the cathode layer 12 reflects light emitted from the light-emitting layer 110b toward the substrate 2, it is preferable that the cathode layer 12 be formed of an Ag film or a laminated film of the Al film and the Ag film, in addition to the Al film. In addition, a protective layer for preventing oxidization, made of SiO, SiO₂, SiN or the like, may be provided on the aluminum film.

In an actual organic EL device, a sealing portion is provided on the light-emitting element portion 11 shown in FIG. 5. The sealing portion can be formed by applying a sealing resin around the periphery of the substrate 2 in a ring shape and then by sealing it with a sealing can. The sealing resin is composed of a thermosetting resin or an ultraviolet curable resin. In particular, it is preferable that the sealing resin be composed of an epoxy resin, which is a kind of thermosetting resin. The sealing portion is provided in order to prevent the light-emitting layer formed in the cathode layer 12 or light-emitting element portion 11 from being oxidized. In addition, a getter agent may be provided in the sealing can to absorb water and oxygen permeating the sealing can.

FIG. 6 is a diagram showing the cross-sectional structure of a second display region 22 composed of only red dots (sub-pixels) A1. In addition, the second display region 22 has the same sectional structure as that of the first display region 21 shown in FIG. 5, except for the structure of the light-emitting layer 110b. Therefore, the detailed description thereof will be omitted.

In the second display region 22, three red dots A1 constitute one pixel, and each dot A1 is provided with a red light-emitting layer 110b1 for emitting a light red (R) component.

Further, in the first display region 21, LiF may be formed between the light-emitting layer 110b and the cathode layer 12 in order to improve the light-emitting efficiency. However, since there is a fear that the light-emitting efficiency is deteriorated in the second display region 22, it is preferable that the LiF not be provided in the second display region 22.

According to the organic EL device having the above-mentioned structure, the display region 2a includes the first display region 21 to perform full-color display and the second display region 22 to perform monochrome display. In this case, the pixels for full-color display are not arranged over the entire region of the display region 2a. However, the pixels to emit necessary color light components can be arranged on a predetermined region (second display region 22), and the pixels to emit unnecessary color light components can be excluded in the second display region 22. As a result, the aperture ratio can be improved as a whole. In addition, only the pixels corresponding to the necessary colors are arranged in the predetermined region (second display region 22). Therefore, even if the brightness per pixel decreases, the same brightness as that in the related art can be obtained, compared to the related art in which the pixels for full-color display are arranged over the entire display region 2a. Thus, the deterioration of brightness per pixel can be reduced, and it is possible to reduce consumption power and to prolong the life span.

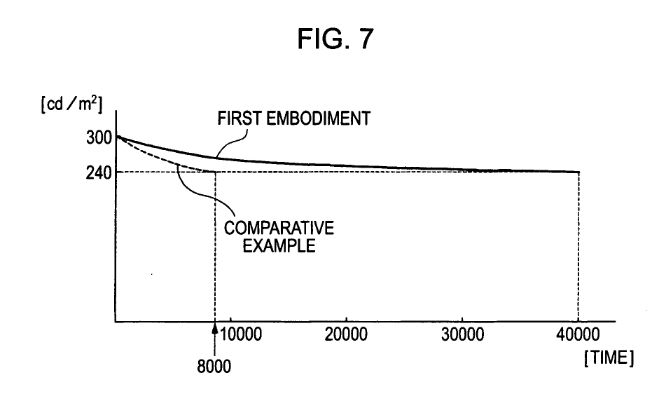

More particularly, as shown in FIG. 7, the life span increases. FIG. 7 is a graph showing time variation with respect to the brightness (first embodiment) in the second display region 22 of the organic EL device according to the present embodiment and the brightness (comparative example) in a case in which the entire display region is composed of pixels for full-color display. In addition, the vertical axis indicates brightness per pixel (cd/m²) in the surface, and the horizontal axis indicates time (hour).

As shown in FIG. 7, according to the organic EL device of the present embodiment, when the pixel is set such that the surface brightness of an initial value of 300 cd/m² is obtained in one pixel with respect to the organic EL devices according to the first embodiment and the comparative example, the time when brightness becomes 80% of the initial value is 8000 hours in the comparative example, but is 40000 hours in the first embodiment. That is, by using the structure of the present embodiment, it is possible to lengthen the time for brightness to deteriorate by five times.

In addition, in the organic EL device according to the present embodiment, the resolution can be improved. That is, as compared to the case in which the pixels for full-color display are arranged over the entire display region 2a, it is possible to increase the number of pixels corresponding to necessary colors in the predetermined region (second display region 22) and thus to improve resolution.

In addition, according to the present embodiment, the first display region 21 is used for full-color display, and the second display region 22 is used for monochrome display. However, the first display region 21 may be used for full-color display, and the second display region 22 may be used for two-color display. Alternatively, the first display region 21 may be used for two-color display, and the second display region 22 may be used for monochrome display. In addition, the display region for monochrome display may be formed of a white light-emitting material to emit a white light component. Therefore, it is possible to constitute the display region 2a having large variations.

Method of Manufacturing Organic EL Device

Next, a method of manufacturing the organic EL device will be described with reference to the accompanying drawings.

A method of manufacturing the organic EL device according to the present embodiment includes (1) a process of forming a bank portion, (2) a process of forming a hole injection/transportation layer, (3) a process of forming a light-emitting layer, (4) a process of forming a cathode layer, and (5) a process of performing sealing. Since this method is just an illustrative example, other processes can be added, and some of the above-mentioned processes can be removed, if necessary.

In addition, (2) the process of forming the hole injection/transportation layer and (3) the process of forming the light-emitting layer are performed by a liquid ejecting method (inkjet method) using a liquid droplet ejecting device (inkjet device).

(1) Process of Forming Bank Portion

In the process of forming the bank portion, the bank portion 112 is formed at a predetermined location of the substrate 2. The bank portion 112 has the inorganic bank layer 112a, functioning as a first bank layer, and the organic bank layer 112b, functioning as a second bank layer.

(1)-1 Forming Inorganic Bank Layer 112a

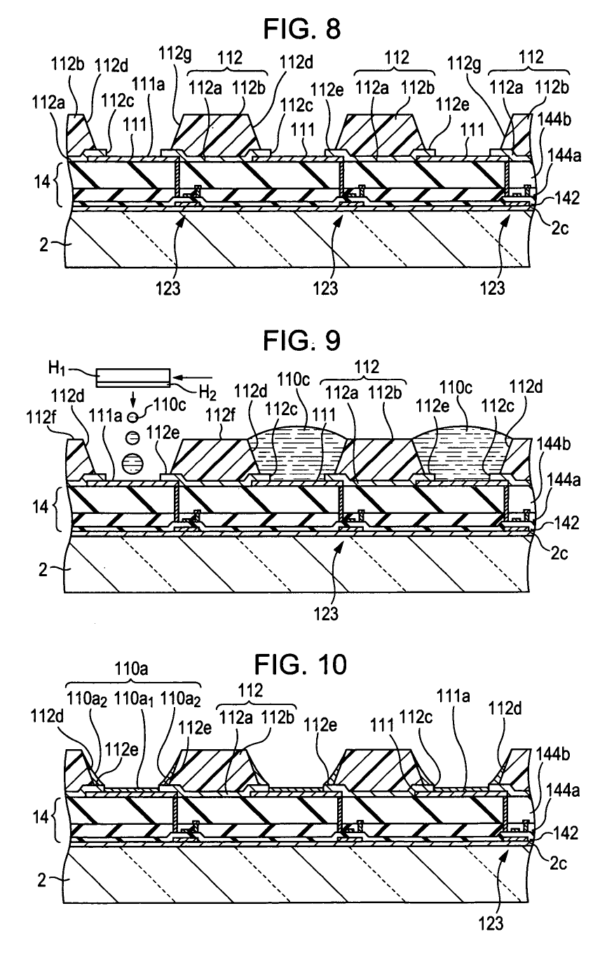

As shown in FIG. 8, first, the inorganic bank layer 112a is formed at a predetermined location of the substrate. The location where the inorganic bank layer 112a is formed is on the second interlayer insulating film 144b and the pixel electrode 111. In addition, the second interlayer insulting film 144b is formed on the circuit element unit 14 in which the thin film transistors, the scanning lines, the signal lines, and the like are arranged. The inorganic bank layer 112a can be made of, an inorganic material, such as SiO₂ or TiO₂. These materials can be formed by, for example, a CVD method, a coating method, a sputtering method, or a vapor deposition method. In addition, preferably, the thickness of the inorganic bank layer 112a is within the range of 50 to 200 nm, and more preferably, 150 nm.

The inorganic bank layer 112a is formed to have an opening by forming an inorganic film on the entire surface of the interlayer insulating layer 144 and the pixel electrode 111 and then by patterning the inorganic film using a photolithography method. The opening is adjacent to the electrode surface 111a of the pixel electrode 111 and is provided as a lower opening 112c, as shown in FIG. 8. In addition, the inorganic bank layer 112a is formed so as to partially overlap a peripheral portion of the pixel electrode 111, so that a two-dimensional light-emitting region of the light-emitting layer 110 is controlled.

(1)-2 Forming Organic Bank Layer 112b

Next, the organic bank layer 112b, functioning as a second bank layer, is formed.

Particularly, as shown in FIG. 8, the organic bank layer 112b is formed on the inorganic bank layer 112a. The organic bank layer 112b is made of a material having heat resistance and solvent resistance, such as an acrylic resin or a polyimide resin. Using these materials, the organic bank layer 112b is formed by patterning it using a photography technology. In addition, when it is patterned, the upper opening 112d is formed in the organic bank layer 112b. The upper opening 112d is provided at a location adjacent to the electrode surface 111a and the lower opening 112c, and has a pattern common to all pixels.

As shown in FIG. 8, it is preferable that the upper opening 112d be larger than the lower opening 112c formed on the inorganic bank layer 112a in diameter. In addition, it is preferable that the organic bank layer 112b have a taper shape in sectional view. Further, it is preferable that a bottom surface of the organic bank layer 112b have a width smaller than that of the pixel electrode 111, and that a top surface of the organic bank layer 112b have a width substantially equal to that of the pixel electrode 111.

Thereby, the first laminated portion 112e surrounding the lower opening 112c of the inorganic bank layer 112a more protrudes to the central side of the pixel electrode 111 than to the organic bank layer 112b. In this way, the upper opening 112d formed on the organic bank layer 112b and the lower opening 112c formed on the inorganic bank layer 112a communicate with each other, so that the opening 112g passing through the inorganic bank layer 112a and the organic bank layer 112b is formed.

It is preferable that a suitable surface treatment by a plasma treatment be performed on the surfaces of the bank portion 112 and the pixel electrode 111. In particular, a lyophobic treatment is performed on the surface of the bank portion 112, and a lyophilic treatment is performed on the surface of the pixel electrode 111. The surface treatment of the pixel electrode 111 can be performed by an 02 plasma treatment using oxygen gas. For example, it is possible to make the region including the surface of the pixel electrode 111 have a lyophilic property by performing the plasma treatment under the conditions of a plasma power of 100 to 800 kW, an oxygen gas flow rate of 50 to 100 ml/min, a plate carrying speed of 0.5 to 10 mm/sec, and a substrate temperature of 70 to 90° C. In addition, cleaning the surface of the pixel electrode 111 by the O2 plasma treatment and adjusting the work function are simultaneously performed. Next, the surface treatment of the bank portion 112 can be performed by a CF4 plasma treatment using tetrafluoromethane. For example, it is possible to make the region including the upper opening 112d and the top surface 112f of the bank portion 112 have a lyophobic property by performing the plasma treatment under the conditions of a plasma power of 100 to 800 kW, a methane tetrafluoride gas flow rate of 50 to 100 ml/min, a substrate carrying speed of 0.5 to 10 mm/sec, and a substrate temperature of 70 to 90° C.

(2) Process of Forming Hole Injection/Transportation Layer

Next, in the process of forming the light-emitting element, first, the hole injection/transportation layer is formed on the pixel electrode 111.

In the process of forming the hole injection/transportation layer, using an inkjet device as a liquid droplet ejecting device, a liquid composition containing the material for forming the hole injection/transportation layer is ejected onto the electrode surface 111a. After that, by performing a drying treatment and a heat treatment, the hole injection/ transportation layer 110a is formed on the pixel electrode 111 and the inorganic bank layer 112a. In addition, the hole injection/transportation layer 110a may not be formed on the first laminated portion 112e. That is, the hole injection/transportation layer 110a may be formed only on the pixel electrode 111.

A method of forming the hole injection/transportation layer using an inkjet method is as follows. That is, as shown in FIG. 9, a liquid composition containing the material for forming the hole injection/transportation layer is ejected from a plurality of nozzles provided in an inkjet head H1. Here, by moving the inkjet head, the composition is applied onto every pixel. However, by moving the substrate 2, the composition can be applied onto every pixel. In addition, by relatively moving the inkjet head and the substrate 2, the composition can be applied onto every pixel. A method of forming a layer using the inkjet head (inkjet method), which will be described below, is the same as the above.

A method of ejecting liquid droplets using the inkjet head is as follows. That is, ejection nozzles H2 formed in the inkjet head H1 are arranged so as to face the electrode surface 111a, and a liquid composition is ejected from the nozzles H2. The bank portions 112 for partitioning the lower openings 112c are formed around the pixel electrodes 111, and the inkjet head H1 faces the pixel electrode surface 111a located inside the lower opening 112c. Then, a liquid droplet 110c of the liquid composition whose flow rate is controlled for each liquid droplet is ejected onto the electrode surface 111a from the ejection nozzles H2 while relatively moving the inkjet head H1 and the substrate 2.

As the liquid composition used in the current process, for example, it is possible to use a composition obtained by dissolving a mixture of a polythiophene derivative, such as polyethylenedioxothiophene (PEDOT), and polystyrene sulfonic acid (PSS) into a polar solvent. The polar solvents may include, for example, isopropyl alcohol (IPA), normal buthanol, gamma-butyrolactone, N-methylpyrrolidone (NMP), 1,3-dimethyl-2-imidazolidinone (DMI) and a derivative thereof, and glycol ethers, such as carbitol acetate and butyl carbitol acetate.

More particularly, the following compositions can be used: a PEDOT/PSS mixture (PEDOT/PSS=1:20): 12.52% by weight, IPA: 10% by weight, NMP: 27.48% by weight, and DMI: 50% by weight. In addition, preferably, the liquid composition has a viscosity of about 1 to 20 mPa.s, and more preferably, a viscosity of about 4 to 15 mPa.s.

By using the above-mentioned liquid composition, it is possible to stably eject the liquid droplet without generating clogging of the ejection nozzle H2. In addition, the materials for forming the hole injection/transportation layer are the same with respect to the red (R), green (G), and blue (B) light-emitting layers 110b1 to 110b3. The materials may be changed for each light-emitting layer.

The liquid droplets 110c of the ejected composition are diffused on the electrode surface 111a and the first laminated portion 112e having the lyophilic property and are then filled into the lower and upper openings 112c and 112d. Even if the first composition liquid droplet 110c is ejected onto the top surface 112f of the bank portion, deviating from a predetermined ejection location, the top surface 112f is not wet by the first composition liquid droplets 110c, and the ejected first composition liquid droplets 110c flow into the lower and upper openings 112c and 112d.

The amount of a composition to be ejected onto the electrode surface 111a is determined according to the sizes of the lower and upper openings 112c and 112d, the thickness of the hole injection/transportation layer to be formed, the concentration of a material forming the hole injection/transportation layer in the liquid composition. The liquid droplet 110c of the liquid composition may be ejected onto the same electrode surface 111a many times as well as being ejected once. In this case, whenever the liquid droplet 110c is ejected onto the electrode surface, the amount of the liquid droplet may be always the same, or may be changed. In addition, whenever the liquid droplet 110c is ejected onto the electrode surface 111a, the liquid composition may be ejected onto different locations of the electrode surface 111a as well as being ejected at the same location of the electrode surface

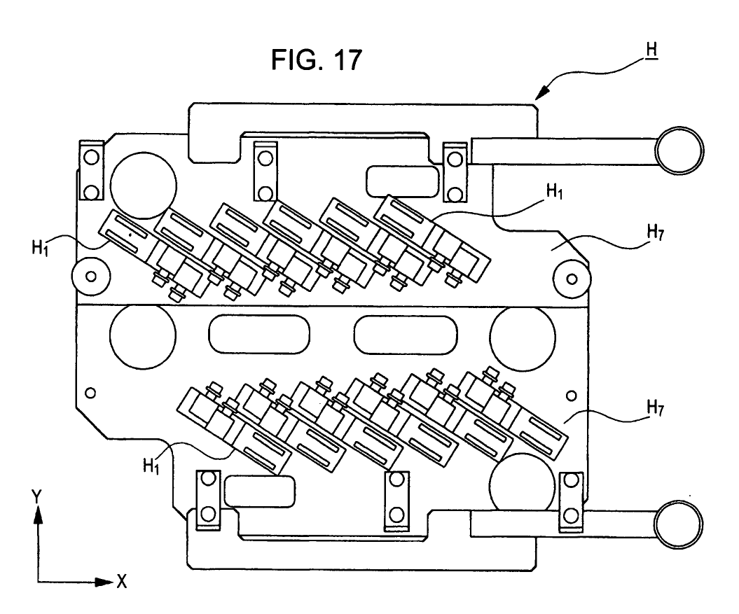

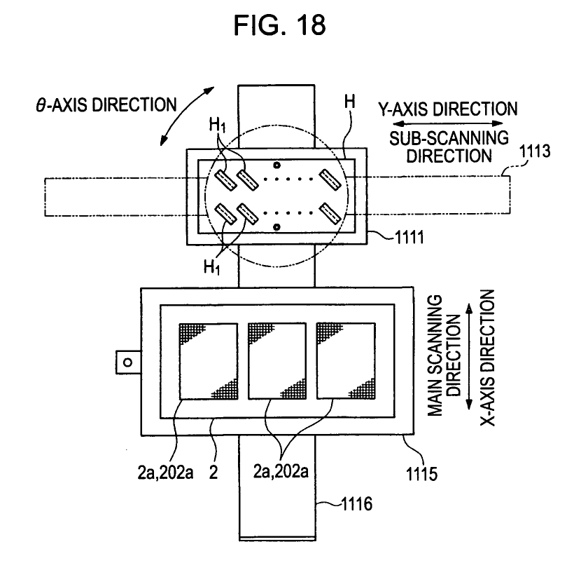

With respect to the structure of the inkjet head, an inkjet head H shown in FIG. 17 can be used. In addition, the substrate and the inkjet head are preferably arranged as shown in FIG. 18. In FIG. 17, reference numeral H7 indicates a supporting substrate for supporting the inkjet head H1, and a plurality of inkjet heads H1 are provided on the supporting substrate H7. On an ink ejection surface of the inkjet head H1 (surface opposite to the substrate), a plurality of ejection nozzles (for example, 180 nozzles are aligned in a row, and thus a total of 360 nozzles is arranged) are provided along a longitudinal direction of the head in a row and at a gap along a width direction in two rows. In addition, the ejection nozzles of the inkjet head H1 extend toward the substrate. In addition, the ejection nozzles are arranged along the X-axis direction in a row in a state in which they are inclined at a predetermined angle with respect to the X-axis (or the Y-axis), and are plurally located on a supporting plate 20 having a rectangular shape in plan view (in FIG. 17, six in a row, and a total of 12 places) in a state in which they are arranged in two rows at a predetermined gap in the Y direction.

In addition, in FIG. 18, reference numeral 1115 indicates a stage for mounting the substrate 2, and reference numeral 1116 indicates a guide rail for guiding the stage 1115 in the x-axis direction (main scanning direction). Further, the head H can be moved by a guide rail 1113 via a supporting member 1111 in the y-axis direction (sub-scanning direction). In addition, the head H can be rotated in the θ-axis direction in FIG. 18, and the inkjet head H1 can be inclined by a predetermined angle with respect to the main scanning direction. In this way, the inkjet head is arranged so as to be inclined with respect to the scanning direction, so that it is possible to make a nozzle pitch equal to a pixel pitch. In addition, by adjusting an inclined angle of the inkjet head, it is possible to make the nozzle pitch to be equal to any pixel pitch.

As shown in FIG. 18, the substrate 2 has a structure in which a plurality of chips are arranged on a mother substrate, that is, a region occupied by one chip corresponds to one display device. Here, three display regions 2a are formed, but the invention is not limited thereto. For example, when the composition is applied onto the display region 2a located at the left of the substrate 2, the head H is moved through the guide rail 1113 toward the left side of the drawing, and the substrate 2 is moved through the guide rail 1116 toward the upper side of the drawing, thereby applying the composition onto the display region 2a while scanning the substrate 2. Next, the head H is moved toward the right side of the drawing, and the composition is applied on the display region 2a located at the center of the substrate. In the same manner, the composition is applied on the display region 2a located at the right end of the substrate. In addition, the head H shown in FIG. 17 and the inkjet device shown in FIG. 18 are used for forming the light-emitting layer as well as forming the hole injection/ transportation layer.

Next, as shown in FIG. 10, a drying treatment is performed. In other words, after ejecting the first composition, the first composition is dried, so that a solvent contained in the first composition is evaporated, thereby forming the hole injection/transportation layer 110a. When the drying treatment is performed, the evaporation of the solvent contained in the liquid composition occurs mainly at a portion adjacent to the inorganic bank layer 112a and the organic bank layer 112b, and at the same time, the material forming the hole injection/transportation layer is concentrated and then deposited. As a result, as shown in FIG. 10, the peripheral portion 110a2 made of the hole injection/transportation layer forming material is formed on the first laminated portion 12e. The peripheral portion 110a2 adheres closely to the wall surface of the upper opening 112d (organic bank layer 112b), and has a small thickness at a part near to the electrode surface 111a and a large thickness at a part away from the electrode surface 111a, that is, near to the organic bank layer 112b.

Further, at the same time, the evaporation of the solvent occurs on the electrode surface 111a through the drying treatment, so that the flat portion 110a1 made of the hole injection/transportation layer forming material is formed on the electrode surface 111a. Since the evaporation speed of the solvent is almost constant on the electrode surface 111a, the hole injection/transportation layer forming material is uniformly concentrated on the electrode surface 111a, so that the flat portion 110a1 having a uniform thickness is formed. In this way, the hole injection/transportation layer 110a composed of the peripheral portion 110a2 and the flat portion 110a1 is formed. In addition, the hole injection/transportation layer may be formed only on the electrode surface 111a, not on the peripheral portion 110a2.

The drying treatment is performed under a pressure of, for example, 133.3 Pa (1 Torr) at room temperature in nitrogen atmosphere. If the pressure is excessively low, the liquid droplet 110c of the composition is bumped, so it is not desirable. In addition, if temperature is higher than room temperature, the evaporation speed increases, so that it is not possible to form a flat film. After the drying treatment, it is preferable that the polarity solvent or water remaining in the hole injection/transportation layer 110a be removed by performing a heat treatment for ten minutes at a temperature of 200 ° C. in nitrogen atmosphere, preferably, in vacuum atmosphere.

(3) Process of Forming Light-Emitting Layer

The process of forming the light-emitting layer includes a process of ejecting a light-emitting layer forming material and a drying treatment process.

Similar to the above-mentioned hole injection/transportation layer forming process, a liquid composition for forming the light-emitting layer is ejected onto the hole injection/transportation layer 110a by the inkjet method. Then, the ejected liquid composition is dried (and thermally treated), and thus the light-emitting layer 110b is formed on the hole injection/transportation layer 110a.

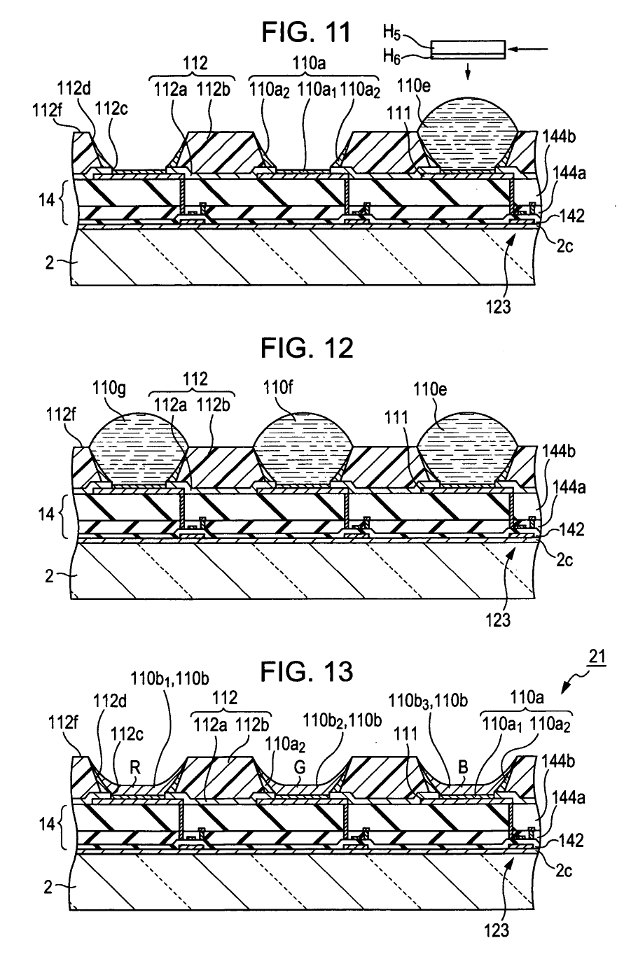

FIG. 11 shows a process of ejecting the liquid composition containing the light-emitting layer forming material using the inkjet method. As shown in FIG. 11, the liquid composition containing light-emitting layer forming materials for each color (in this embodiment, for example, blue (B)) is ejected from the ejection nozzles H6 provided in the inkjet head while relatively moving the inkjet head H5 and the substrate 2.

At the time when the liquid composition is ejected, with the ejection nozzles facing the hole injection/transportation layer 110a located inside the lower and upper openings 112c and 112d, the liquid composition is ejected while relatively moving the inkjet head H5 and the substrate 2. The amount of liquid per droplet ejected from the ejection nozzle H6 is controlled. As such, the liquid droplet whose amount is controlled is ejected onto the hole injection/transportation layer 110a from the ejection nozzle.

As shown in FIG. 2, according to the present embodiment, since dot patterns corresponding to the respective colors are different from each other in the first display region 21 and the second display region 22, each region has a different ejection aspect.

As shown in FIG. 12, in the first display region 21, liquid droplet compositions 110f and 110g containing different color light-emitting layer forming materials are ejected without drying a liquid droplet composition 110e dropped on the substrate 2. On the other hand, the liquid droplet composition 110g containing a red light-emitting layer forming material is ejected in the second display region 22. That is, according to the present embodiment, since the ejection process is performed by the inkjet method, it is possible to selectively eject compositions having predetermined colors onto predetermined dots.

As shown in FIG. 12, the ejected liquid compositions 110e to 110g are diffused on the hole injection/transportation layer 110a to fill into the lower and upper openings 112c and 112d. On the top surface 112f subjected to the lyophobic treatment, even though the respective liquid compositions 110e to 110g are ejected onto the top surface 112f deviating from predetermined locations, the top surface 112f is not wet with the liquid compositions 110e to 110g, and the liquid compositions 110e to 110g flow into the upper and lower openings 112c and 112d.

Further, a dummy pixel is arranged at the interface between the first display region 21 and the second display region 22. The dummy pixel has an opening surrounded by the bank portions 112. However, since the liquid droplet is not ejected onto the dummy pixel, the light-emitting layer is not formed.

As described above, on the first display region 21, the liquid composition containing the light-emitting layer forming materials corresponding to red, green and blue is ejected. On the other hand, on the second display region 22, the liquid composition containing the red light-emitting layer forming material is ejected. In this case, when the first display region 21 and the second display region 22 are consecutively formed, color mixture may occur at the interface between the first display region 21 and the second display region 22. However, as in the present embodiment, the dummy pixels are arranged, so that it is possible to prevent the generation of a display defect caused by the color mixture. In addition, it is preferable that a light-shielding portion be provided in the dummy region so as to overlap it in plan view.

In the present embodiment, materials for forming the light-emitting layer may be a polyfluorene-based polymer derivative, a (poly)paraphenylenevinylene derivative, a polyphenylene derivative, a polyvinylcarvazole, a polythiophene derivative, a perylene dye, a coumarin dye, a rhodamine dye, and materials obtained by doping an organic EL material to the above-mentioned polymer materials. For example, the materials may be obtained by doping rubrene, perylene, 9,10-diphenylanthracene, tetraphenylbutadiene, Nile red, coumarin 6, quinacridone, or the like into these polymer materials. In addition, the same kind of solvent is used for each color light-emitting layer for dissolving or dispersing these light-emitting layer forming materials.

Next, the drying treatment is performed. In the first display region 21, after the liquid compositions 110e to 110g are arranged at predetermined locations, the drying treatment is performed over the entire region to form light-emitting layers 110b 1 to 110b3. That is, the solvent contained in the liquid compositions 110e to 110g is evaporated by the drying treatment, so that a red (R) light-emitting layer 110b 1, a green (G) light-emitting layer 110b2, a blue (B) light-emitting layer 110b3 are formed, as shown in FIG. 13. Further, only three red, green, and blue light-emitting layers are shown in FIG. 13. However, as can apparently be seen from FIG. 2 and other drawings, the light-emitting elements are arranged in a matrix, and a plurality of light-emitting layers (not shown) are formed for each color in the invention.

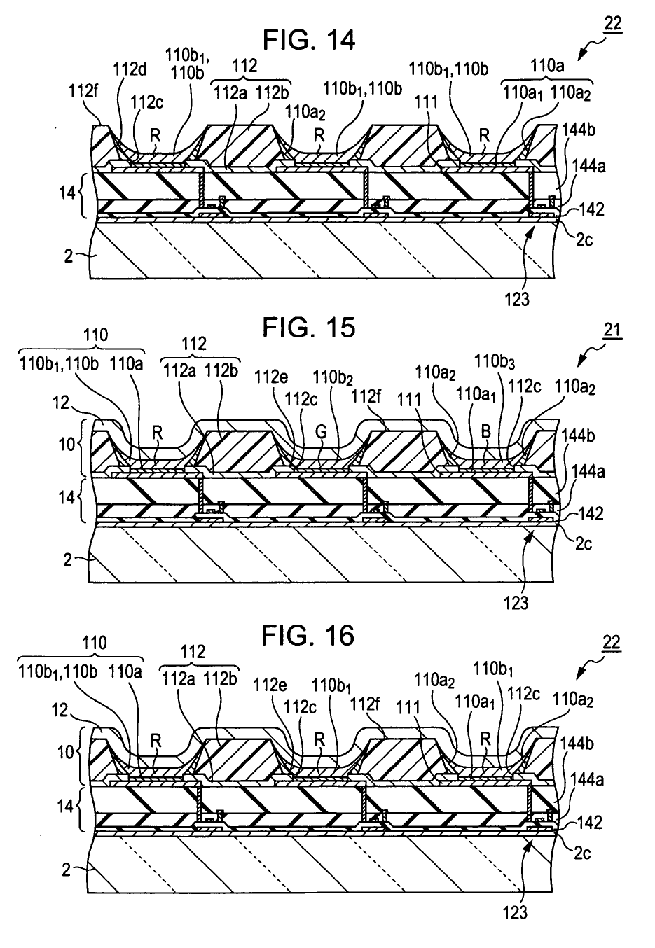

On the other hand, in the second display region 22, the red liquid composition 110g is arranged, and then the light-emitting layer 110b1 is formed by the drying treatment. That is, the solvent contained in the liquid composition droplet 110g is evaporated to form the red (R) light-emitting layer 110b1 shown in FIG. 14.

It is preferable that the drying of the liquid composition be performed by the vacuum drying. More particularly, the drying treatment can be performed under a pressure of 133.3 Pa (1 Torr) at room temperature in nitrogen atmosphere. If the pressure is excessively low, the liquid composition is bumped, so that it is not desirable. In addition, if the temperature is higher than room temperature, the evaporation speed of the solvent increases. As a result, since a large amount of light-emitting layer forming material is stuck on the wall surface of the upper opening 112d, it is not desirable.

Next, when the drying treatment is completed, preferably, the light-emitting layer 110b is annealed by using a heating unit, such as a hot plate. The annealing treatment is performed at the same temperature and time at which the light-emitting characteristics of the respective organic EL layers can be maximally exhibited.

In this way, the hole injection/transportation layer 110a and the light-emitting layer 110b are formed on the pixel electrode 111.

(4) Process of Forming Cathode Layer

Next, as shown in FIGS. 15 and 16, the cathode layer 12 forming a couple together with the pixel electrode (anode layer) 111 is formed in the first and second display regions 21 and 22. That is, the cathode layer 12 composed of a laminated structure of an aluminum layer and a calcium layer is formed on the entire surface of the substrate 2 including the respective color light-emitting layers 110b and the organic bank layers 112b. In this way, the cathode layer 12 is deposited on the entire surface of the region for forming the respective color light-emitting layers 110b, and the organic EL elements corresponding to red, green, and blue are respectively formed.

Preferably, the cathode layer 12 is formed by using a vapor deposition method, a sputtering method, or a CVD method. Particularly, it is preferable to use the vapor deposition method because the damage of the light-emitting layer 110b due to heat can be prevented. In addition, in order to prevent oxidization, a protective layer made of SiO₂ or SiN may be formed on the cathode layer 12.

(5) Process of Performing Sealing

Finally, the substrate 2 having the organic EL element formed thereon and a separately prepared sealing substrate are sealed with a sealing resin. For example, the sealing resin made of a thermosetting resin or an ultraviolet curable resin is applied onto the periphery of the substrate 2, and then the sealing substrate is arranged on the substrate on which the sealing resin is applied. It is preferable that the sealing process be performed in the atmosphere of an inert gas, such as oxygen, argon, or helium. In a case in which the sealing process is performed in the air, if a defect, such as a pinhole, occurs in the cathode layer 12, water or oxygen is permeated into the cathode layer 12 through the defective portion, which causes the cathode layer 12 to be oxidized. Therefore, this method is undesirable.

Thereafter, the cathode layer 12 is connected to the wiring lines of the substrate 2, and the wiring lines of the circuit element unit 14 are connected to a driving IC (driving circuit) provided on the substrate 2 or at the outside thereof, thereby completing an organic EL device according to the present embodiment.

Electronic Apparatus

Next, an electronic apparatus including the display device according to the invention will be described.

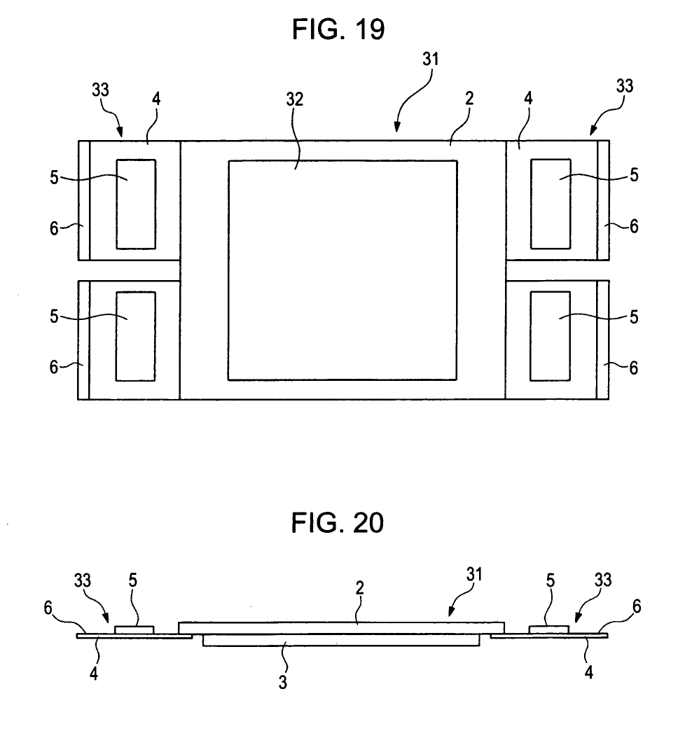

First, a description will be made with respect to a case in which the display device having the same structure as the organic EL device according to the present embodiment is used for a display unit of an instrument panel. FIG. 19 is a plan view schematically showing the structure of a substrate for a display unit included in the instrument panel, and FIG. 20 is a cross-sectional view schematically showing the structure of the substrate for a display unit.

The display unit has as a main element a main display unit 31 having a structure in which the organic EL layer is interposed between the substrate 2 having the TFTs thereon and a sealing glass 3, and a display surface 32 is arranged at a central portion of the main display unit 31. In addition, an external connecting portion 33 includes a flexible substrate 4 connected to the substrate 2 and a data line driving IC 5 disposed on the flexible substrate 4. The external connecting portion 33 is connected to the main display unit 31, and external connecting terminals 6 are provided to one end of the external connecting portion 33.

Further, on the substrate 2, a transistor array and a data holding circuit are provided. A scan driver is built in the substrate 2. Furthermore, the data lines, the control lines, and the power lines are provided on the flexible substrate 4, and the data line driving IC has a function for supplying data to each dot (sub-pixel). In addition, the external connecting terminals 6 are a terminal supplied with a control signal from an external control substrate (not shown) and a terminal supplied with power from a power supply substrate.

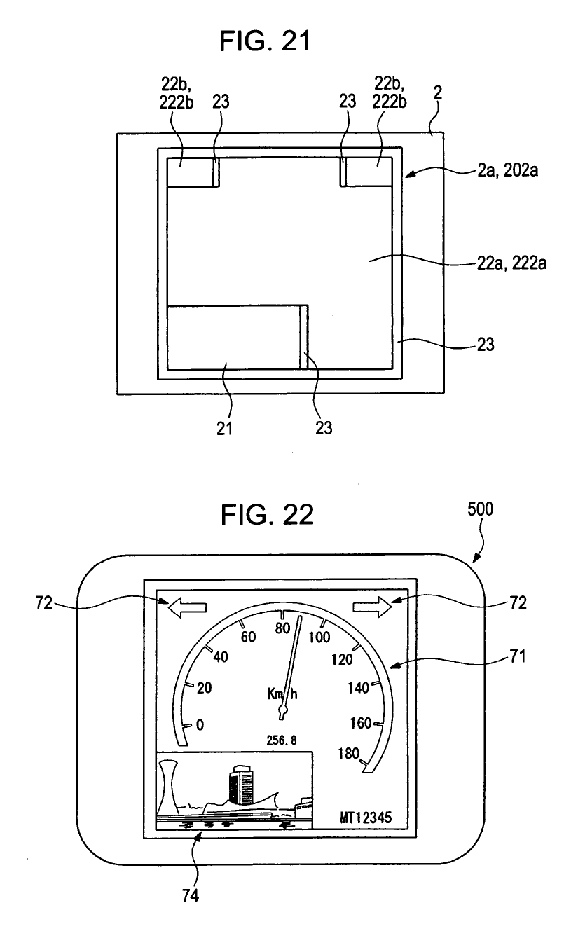

On the other hand, FIG. 21 is a diagram illustrating the structure of a display region in the mounted display unit. The organic EL device shown in FIG. 2 has two display regions having different color display ranges. However, a display region 2a of the main display unit has a red display region 22a to perform only red display corresponding to, a blue display region 22b to perform only blue display, and a full-color display region 21 to perform full-color display. Here, at boundary regions between the respective display regions, dummy pixel regions 23 are formed, and regions in which display is not performed, that is, pixel regions in which the light-emitting layers are not provided are formed. Alternatively, the light-emitting layers may formed in the boundary regions, so that it is possible to make no current flow through the control circuit.

Further, in the dummy pixel region 23, three pixels (that is, nine dots (sub-pixels)) are formed in the width-wise direction thereof. Furthermore, the display region 2a of the display unit has pixels of 560 ′ 560 in total, and one pixel has three dots (sub-pixels). The dummy pixels 23 are provided in the peripheral portion of the display region 2a.

The display unit having the above-mentioned structure is mounted on an instrument panel portion 500, as shown in FIG. 22. More particularly, the flexible substrate 4 is incorporated into the instrument panel portion 500. When the red display region 22a serves as a meter display unit 71 to perform speed display in an automobile, ON display is normally performed on the red display region 22a. On the other hand, when the blue display region 22b serves as a necessary information display unit 72 to display information necessary for driving, ON display is performed on the blue display region 22b in accordance with information output timing. Moreover, the full-color display region 21 serves as an arbitrary information display unit 74 for performing full-color display additionally necessary information, such as external information from a mounted camera or navigation information from a navigation system.

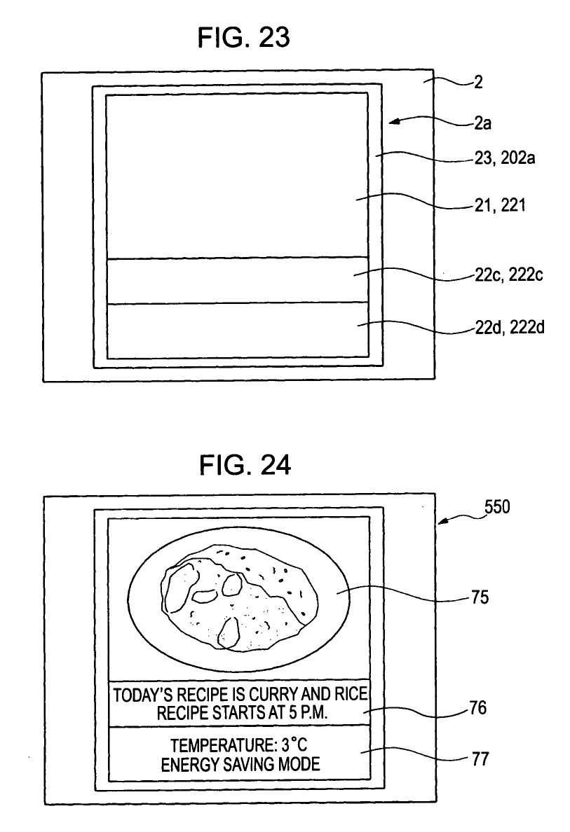

Next, a description will be made with respect to a case in which a display device having the same structure as the organic EL device according to the present embodiment is applied to a display unit of an electric home appliance. FIG. 23 is a plan view schematically showing the structure of a display panel attached to a refrigerator, and FIG. 24 is a plan view showing the state of use of the refrigerator. In addition, since the structure of the substrate is the same as that used for the instrument panel, a detailed description thereof is omitted.

A display region 2a of the display panel used for the present embodiment includes a full-color display region 21 to perform full-color display, an orange display region 22c to perform only monochrome display corresponding to orange, and a red display region 22d to perform only monochrome display corresponding to red. In addition, the orange display region 22c is composed of pixels each having two red dots (sub-pixels) and one green dot (sub-pixel). Further, the dummy pixel region 23 is formed in a peripheral portion of the display region 2a.

The display panel having the above-mentioned structure is mounted on a display unit 550 of the refrigerator, as shown in FIG. 24. More particularly, the red display region 22d serves as an operation state display unit 77 for displaying the operation state of and temperature in the refrigerator, and the orange display region 22c serves as a service information display unit 76 for displaying service information. According to the present embodiment, a recipe is displayed on a daily basis. Furthermore, the full-color display region 21 serves as an image display unit 75 for displaying image information accompanying the service information.

In the electronic apparatus having the above-mentioned structure, the variation of display increases, and the display device of to the invention is also provided. Therefore, it is possible to achieve an electronic apparatus capable of displaying a high-quality image with a long life span.

### Second Embodiment

Organic EL Device

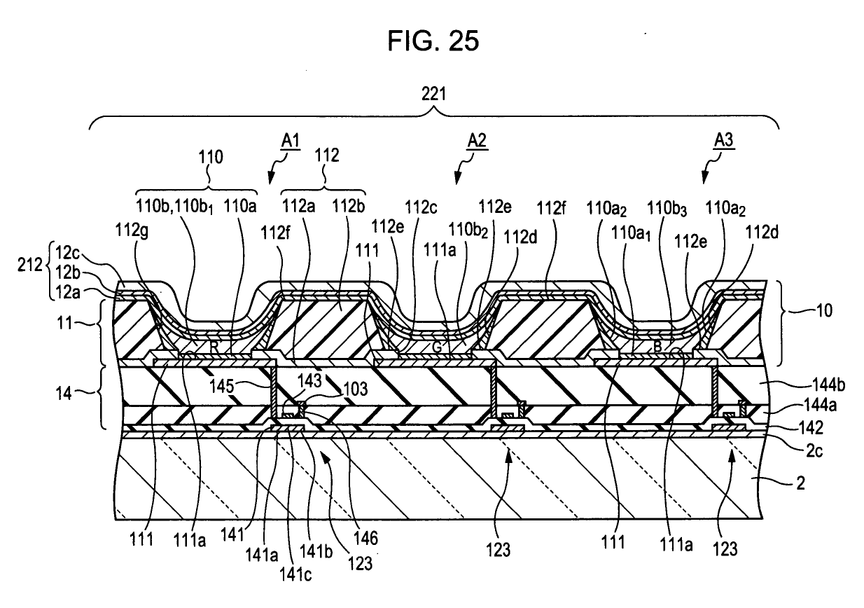

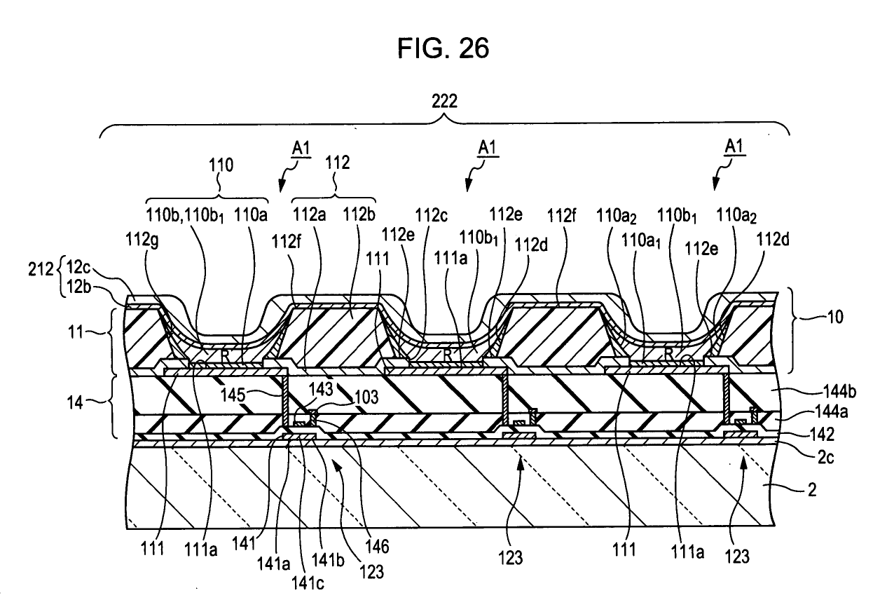

FIG. 1 is a diagram illustrating the wiring structure of an organic EL device according to a second embodiment, and FIG. 2 is a plan view schematically showing the organic EL device according to the second embodiment. FIGS. 3 and 4 are enlarged plan views schematically showing the structure of a pixel, and FIGS. 25 and 26 are cross-sectional views schematically illustrating a display region of the organic EL device according to the second embodiment.

Since the wiring structure of the organic EL device, the structure of the pixel, and the display region shown in these drawings are similar to those in the first embodiment, the same constituent elements as those in the first embodiment are denoted by the same reference numerals, and a description thereof will be omitted.

In a first display region 221, a cathode layer 212 according to the second embodiment has a laminated structure of a lithium fluoride layer 12a, a calcium layer 12b, and an aluminum layer 12c. In this case, it is preferable that a work function be small in a part of the cathode layer adjacent to the light-emitting layer. More particularly, according to the present embodiment, the cathode layer directly comes into contact with a light-emitting layer 110b of an organic EL layer 110 to inject electrons into the light-emitting layer 110b.

The aluminum layer 12c forming the cathode layer 212 reflects light emitted from the light-emitting layer 110b toward the substrate 2, and it is preferable that the aluminum layer 12c be composed of a silver layer or a laminated layer of the aluminum layer and the silver layer, in addition to the aluminum layer. In addition, a protective film for preventing oxidization, made of SiO, SiO₂, or SiN, may be formed on the aluminum layer 12c. In the respective layers constituting the cathode layer 212 in the first display region 221, the lithium fluoride layer 12a quality has a thickness of about 5 nm, the calcium layer 12b has a thickness of about 5 nm, and the aluminum layer 12c has a thickness of about 200 nm.

FIG. 26 is a diagram showing the sectional structure of a second display region 222 composed of only red dots (sub-pixels) A1. The second display region 222 is different from the first display region 221 shown in FIG. 25 in the structures of the light-emitting layer 110b and the cathode layer 212. Since the second display region 222 has the same structure as the first display region 221, except for the structures of the light-emitting layer 110b and the cathode layer 212, a description thereof will be omitted.

In the second display region 222, three red dots A1 constitute one pixel, and a red light-emitting layer 110b1 to emit a red (R) light component is arranged in each dot A1. As shown in FIG. 25, the lithium fluoride layer 12a is formed in the first display region 221 so as to increase light-emitting efficiency at a part of the cathode layer 212 near to the light-emitting layer 110b. However, in the second display region 222, the lithium fluoride layer 12a is not formed. This is because the lithium fluoride layer 12a is a functional layer provided so as to increase the light-emitting efficiency of the blue light-emitting layer 110b3 to emit a blue (B) light component among the light-emitting layers 110b. Further, in the respective layers constituting the cathode layer 212 in the second display region 222, the calcium layer 12b has a thickness of about 5 nm, and the aluminum layer 12c has a thickness of about 200 nm.

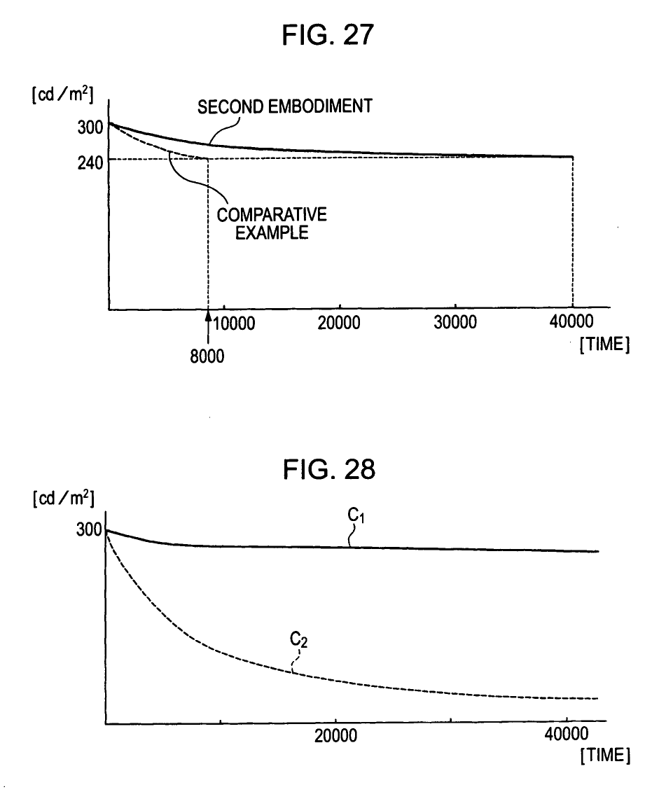

In the organic EL device according to the second embodiment having the above-mentioned structure, similar to the first embodiment, the life span increases, as shown in FIG. 27. FIG. 27 is a graph showing time variation with respect to brightness (second embodiment) in the second display region 222 of the organic EL device according to the present embodiment and brightness (comparative example) in a case in which the entire display region is composed of pixels for full-color display. In addition, the vertical axis indicates brightness per pixel (cd/m²) in the plane, and the horizontal axis indicates time (hour).

As shown in FIG. 27, according to the organic EL device of the present embodiment, when the pixel is set such that the surface brightness of an initial value 300 cd/m² is obtained in one pixel with respect to the organic EL devices according to the second embodiment and the comparative example, the time when brightness becomes 80% of the initial value is 8000 hours in the comparative example, but is 40000 hours in the second embodiment. That is, by using the structure of the present embodiment, it is possible to lengthen the time for which the brightness becomes deteriorated by five times.

In addition, in the organic EL device according to the present embodiment, resolution can be improved. That is, as compared to the case in which the pixels for full-color display are arranged over the entire display region 202a, it is possible to increase the number of pixels corresponding to necessary colors in the predetermined region (second display region 222) and to improve resolution.

Further, in the organic EL device according to the present embodiment, the display region 202a is divided into the first display region 221 and the second display region 222 each of which has a different laminated structure in the functional layer constituting the pixel. More particularly, the cathode layer 212 has the lithium fluoride layer 12a in the first display region 221, and the cathode layer 212 does not have the lithium fluoride layer 12a in the second display region 222. As a result, the light-emitting efficiency is improved for every pixel. Here, in a case in which the lithium fluoride layer 12a is included in the second display region 222, and in a case in which the lithium fluoride layer 12a is not included in the second display region 222, a temporal change of brightness is measured. The measured result is shown in FIG. 28. A curve C1 indicates the temporal change of brightness when the lithium fluoride layer 12a is not included in the second display region, and a curve C2 indicates the temporal change of brightness when the lithium fluoride layer 12a is included in the second display region. As can be seen from FIG. 28, the lithium fluoride layer 12a is not included in the second display region 222, so that the life span of brightness can be considerably improved.

Furthermore, according to the second embodiment, the first display region 221 functions as a full-color display region, and the second display region 222 serves as a monochrome display region. However, similar to the first embodiment, for example, the first display region 221 can serve as the full-color display region, and the second display region 222 can serve as a two-color display region. Alternatively, the first display region 221 can serve as a two-color display region, and the second display region 222 can serve as a monochrome display region. Also, a white light-emitting material may be used for a display region for monochrome display light to emit white light. As a result, it is possible to constitute the display region 202a having a large variation.

Method of Manufacturing Organic EL Device

Next, a method of manufacturing the organic EL device according to the second embodiment will be described with reference to the accompanying drawings. However, a description of the same components as those in the first embodiment will be omitted.

(4) Process of Forming Cathode Layer

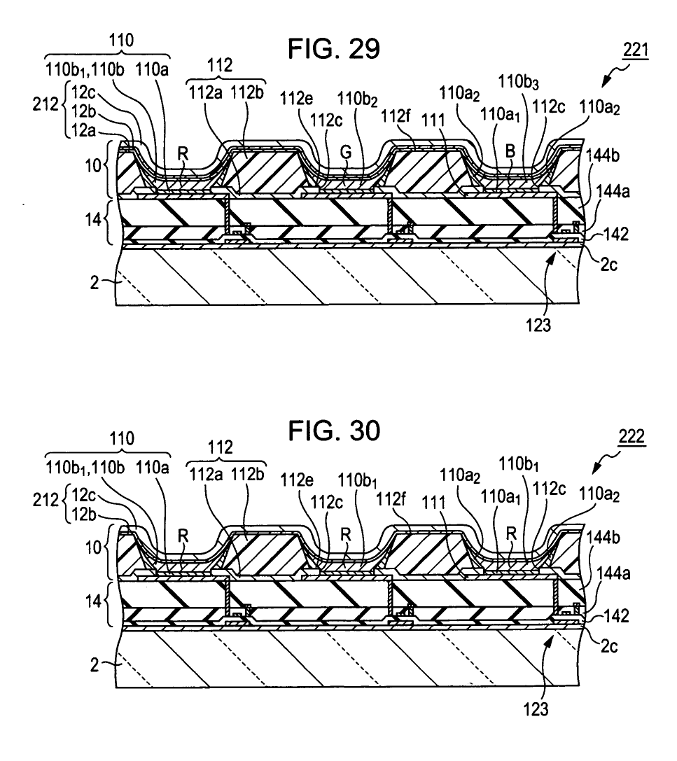

A process of forming the cathode layer different from that in the first embodiment will be described. As shown in FIGS. 29 and 30, the cathode layer 212 which forms a couple together with the pixel electrode (anode layer) 111 is formed on each of the first and second display regions 221 and 222.

That is, in the first display region 221, first, the lithium fluoride layer 12a is formed on the entire surface of the substrate 2 including the respective color light-emitting layers 110b and the organic bank layers 112b shown in FIG. 29, and then the calcium layer 12b and the aluminum layer 12c are sequentially formed thereon. Preferably, the respective layers made of metallic materials are formed using a vapor deposition method, a sputtering method, or a CVD method. Particularly, it is more preferable to use the vapor deposition method because the damage of the light-emitting layer 110b due to heat can be prevented.

On the other hand, in the second display region 222, first, the calcium layer 12b is formed on the entire surface of the substrate 2 including the respective color light-emitting layers 110b and the organic bank layers 112b shown in FIG. 30, and then the aluminum layer 12c is formed thereon. In this case, preferably, the respective layers are formed using the vapor deposition method, the sputtering method, or the CVD method. Particularly, it is more preferable to use the vapor deposition method because the damage of the light-emitting layer 110b due to heat can be prevented.

In this way, the cathode layer 212 is deposited on the region for forming the light-emitting layer 110b in the first display region 221 and the second display region 222, and the organic EL elements corresponding to red, green, and blue can be respectively formed. In addition, in order to prevent oxidization, a protective layer made of SiO₂ or SiN may be formed on the cathode layer 212.

(5) Process of Performing Sealing

Finally, the substrate 2 having the organic EL element formed thereon and a separately prepared sealing substrate are sealed with a sealing resin. For example, the sealing resin made of a thermosetting resin or an ultraviolet curable resin is applied onto the periphery of the substrate 2, and then the sealing substrate is arranged on the substrate on which the sealing resin is applied. It is preferable that the sealing process be performed in the atmosphere of an inert gas, such as oxygen, argon or helium. In a case in which the sealing process is performed in the air, if a defect, such as a pinhole, occurs in the cathode layer 212, water or oxygen is permeated into the cathode layer 212 through the defective portion, which causes the cathode layer 212 to be oxidized. Next, the cathode layer 212 is connected to the wiring lines of the substrate 2, and the wiring lines of the circuit element unit 14 are connected to a driving IC (driving circuit) provided on the substrate 2 or at the outside thereof, thereby completing the organic EL device according to the present embodiment.

Electronic Apparatus

Next, an electronic apparatus including the display device according to the invention will be described. The same constituent elements as those in the first embodiment are denoted by the same reference numerals, and a description thereof will be omitted.

Similar to the first embodiment, the display unit according to the second embodiment is mounted on an instrument panel portion 500, as shown in FIG. 22. More particularly, the display unit is mounted on the instrument panel portion in a manner that the flexible substrate 4 is assembled into the instrument panel portion 500. When the red display region 222a serves as a meter display unit 71 to perform speed display in an automobile, ON display is normally performed on the red display region 222a. On the other hand, when the blue display region 222b serves as a necessary information display unit 72 to display information necessary for driving, ON display is performed on the blue display region 222b in accordance with information output timing. Moreover, the full-color display region 221 can serve as an arbitrary information display unit 74 to perform full-color display of additionally necessary information, such as navigation information from a navigation system or external information from a mounted camera.

Next, a description will be made with respect to a case in which a display device having the same structure as the organic EL device according to the second embodiment is applied to a display unit of an electric home appliance. FIG. 23 is a plan view schematically showing the structure of a display panel attached to a refrigerator, and FIG. 24 is a plan view showing the state of use of the refrigerator. In addition, since the structure of the substrate is the same as that used for the instrument panel, a detailed description thereof will be omitted.

Similar to the first embodiment, a display region 202a of the display panel used for the present embodiment includes a full-color display region 221 to perform full-color display, an orange display region 222c to perform only monochrome display corresponding to orange and a red display region 222d to perform only monochrome display corresponding to red. In addition, the orange display region 222c is composed of pixels each having two red dots (sub-pixels) and one green dot (sub-pixel). Further, a dummy pixel region 23 is formed in a peripheral portion of the display region 202a.

The display panel having the above-mentioned structure is mounted on a display unit 550 of the refrigerator, as shown in FIG. 24. More particularly, the red display region 222d serves as an operation state display unit 77 for displaying the operation state of and temperature in the refrigerator, and the orange display region 222c serves as a service information display unit 76 for displaying service information. According to the present embodiment, a recipe is displayed on a daily basis. Furthermore, the full-color display region 221 serves as an image display unit 75 for displaying image information accompanying the service information.

In the electronic apparatus having the above-mentioned structure, the variation of display increases, and the display device according to the invention is provided. Therefore, it is possible to achieve an electronic apparatus capable of displaying a high-quality image with a long life span.

Until now, the preferred embodiments of the invention have been described, but the invention is not limited to the above-mentioned embodiments. Various changes and modifications can be made without departing from the spirit and scope of the invention. The invention is not limited to the above-mentioned embodiments, but is defined by only the appended claims.

What is claimed is:

1. A display device comprising:
a display region,
wherein the display region includes:
a first display region that is composed of a first pixel group displaying a first light-emitting wavelength range; and
a second display region that is composed of a second pixel group displaying a second light-emitting wavelength range different from the first light-emitting wavelength range.

2. The display device according to claim 1,
wherein the first pixel group is composed of pixels that display plural kinds of color light components, and
the second pixel group is composed of pixels that display a single color light component.

3. The display device according to claim 1,
wherein the first pixel group is composed of pixels each including a first sub-pixel to emit a predetermined color light component and a second sub-pixel to emit another color light component different from the color light component emitted by the first sub-pixel, and
the second pixel group is composed of pixels each having a sub-pixel to emit a predetermined color light component.

4. The display device according to claim 1,
wherein the first pixel group is composed of pixels to perform full-color display, and the second pixel group is composed of pixels to perform monochrome display.

5. The display device according to claim 1,
wherein the first pixel group is composed of pixels each having a sub-pixel to emit a red light component, a sub-pixel to emit a green light component, and a sub-pixel to emit a blue light component, and
the second pixel group is composed of pixels each having two or fewer sub-pixels selected from among the sub-pixel to emit the red light component, the sub-pixel to emit the green light component, and the sub-pixel to emit the blue light component.

6. The display device according to claim 3,
wherein the sub-pixels have the same size.

7. The display device according to claim 3,
wherein the sub-pixels have a rectangular shape, and
the pixel includes a plurality of the sub-pixels having the rectangular shape and has a square shape.

8. The display device according to claim 5,
wherein the sub-pixels have the same size.

9. The display device according to claim 5,
the sub-pixels have a rectangular shape, and
the pixel includes a plurality of the sub-pixels having the rectangular shape and has a square shape.

10. An electronic apparatus comprising the display device according to claim 1.

11. A display device comprising:
a display region,
wherein the display region includes:
a first display region that is composed of a first pixel group displaying a first light-emitting wavelength range and having a plurality of first pixels, each composed of a laminated structure of a plurality of functional layers; and
a second display region that is composed of a second pixel group displaying a second light-emitting wavelength range different from the first light-emitting wavelength range and having a plurality of second pixels, each composed of a laminated structure of a plurality of functional layers, the laminated structure of the second pixels being different from that of the first pixels.

12. The display device according to claim 11,
wherein the first pixel group is composed of first pixels that display plural kinds of color light components, and
the second pixel group is composed of second pixels that display a single color light component.

13. The display device according to claim 11,
wherein the first pixel group is composed of first pixels each including at least a first sub-pixel to emit a predetermined color light component and a second sub-pixel to emit another color light component different from the color light component emitted by the first sub-pixel, and
the second pixel group is composed of second pixels each having a sub-pixel to emit a predetermined color light component.

14. The display device according to claim 11,
wherein the first pixel group is composed of first pixels to perform full-color display, and the second pixel group is composed of second pixels to perform monochrome display.

15. The display device according to claim 11,
wherein the first pixel group is composed of first pixels each having a sub-pixel to emit a red light component, a sub-pixel to emit a green light component, and a sub-pixel to emit a blue light component, and
the second pixel group is composed of second pixels each having two or fewer sub-pixels selected from among the sub-pixel to emit the red light component, the sub-pixel to emit the green light component, and the sub-pixel to emit the blue light component.

16. The display device according to claim 11,
wherein the first pixel group is composed of first pixels each having a sub-pixel to emit a blue light component,
the second pixel group is composed of second pixels each having a sub-pixel to emit a red light component and not having the sub-pixel to emit the blue light component,
a cathode layer containing lithium fluoride, an anode layer, and an organic EL layer formed between the cathode layer and the anode layer serve as a functional layer of the first pixel, and
a cathode layer not containing lithium fluoride, an anode layer, and an organic EL layer formed between the cathode layer and the anode layer serve as a functional layer of the second pixel.

17. The display device according to claim 11,
wherein the first pixel group is composed of first pixels each having a sub-pixel to emit a red light component, a sub-pixel to emit a green light component, and a sub-pixel to emit a blue light component,
the second pixel group is composed of second pixels each having the sub-pixel to emit the red light component,
a cathode layer containing lithium fluoride, an anode layer, and an organic EL layer formed between the cathode layer and the anode layer serve as a functional layer of the first pixel, and
a cathode layer not containing lithium fluoride, an anode layer, and an organic EL layer formed between the cathode layer and the anode layer function as a functional layer of the second pixel.

18. The display device according to claim 16,
wherein the cathode layer constituting the functional layer of the first pixel has a complex structure of lithium fluoride, calcium, and aluminum, and
the cathode layer constituting the functional layer of the second pixel has a complex structure of calcium and aluminum.

19. The display device according to claim 17,
wherein the cathode layer constituting the functional layer of the first pixel has a complex structure of lithium fluoride, calcium, and aluminum, and
the cathode layer constituting the functional layer of the second pixel has a complex structure of calcium and aluminum.

20. An electronic apparatus comprising the display device according to claim 11.
